(19) United States
(12) Patent Application Publication
(10) Pub. No.: US 2006/0049511 A1
(43) Pub. Date: Mar. 9, 2006

(54) Integrated semiconductor circuit and method for producing an integrated semiconductor circuit

(76) Inventor: Andre Schaefer, Munchen (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/214,114

(22) Filed: Aug. 29, 2005

(30) Foreign Application Priority Data
Aug. 31, 2004 (DE) 10 2004 041 961.2

(51) Int. Cl. H01L 23/12

(52) U.S. Cl. 257/700; 257/699; 257/774

(57) ABSTRACT

An integrated semiconductor circuit comprises a substrate with a circuit, a plurality of wiring planes that are isolated from one another and from the substrate by insulator layers, and a signal path for the circuit in the substrate and/or the wiring planes. A first contact terminal, which is formed from a stack of metal areas in a plurality of the wiring planes, is designed for connecting the signal path to an external signal source or an external signal receiver during a test of the integrated semiconductor circuit. A second contact terminal, which is formed from a metal area or from a stack of metal areas in a plurality of wiring planes, is designed for connecting the signal path to an external signal source or an external signal receiver during normal operation of the integrated semiconductor circuit. The distance between the metal area or the bottommost metal area of the stack of the second contact terminal and the substrate is greater than the distance between the bottommost metal area of the stack of the first contact terminal and the substrate.

### CROSS-REFERENCE TO RELATED APPLICATIONS

This application claims foreign priority benefits under 35 U.S.C. §119 to co-pending German patent application number DE 10 2004 041 961.2, filed 31 Aug. 2004. This related patent application is herein incorporated by reference in its entirety.

### BACKGROUND OF THE INVENTION

1. Field of the Invention

The present invention relates to an integrated semiconductor circuit, including an integrated semiconductor circuit with a low electrostatic capacitance between a contact terminal and a substrate, and to a method for producing the semiconductor circuit.

2. Description of the Related Art

An important trend in practically all integrated semiconductor circuits, for example DRAM and other memory components, is toward ever faster data exchange. The magnitude of the electrostatic capacitance of each input and output of an integrated semiconductor circuit may limit performance in this case since the capacitance results in a low-impedance property at high frequencies. To put it another way, a capacitance of an input or output short-circuits the latter at high frequencies. A considerable proportion of the input capacitance is caused by the capacitance of the pad or the contact terminal or the contact pad relative to the substrate.

A contact terminal conventionally comprises a stack of a plurality of metal areas that are formed in a respective one of the wiring planes of the chip. Insulator layers are arranged between the wiring planes. The metal areas of the contact terminal are electrically connected to one another by means of through-hole conductors (vias) or other pillar-type or ridge-type conductive structures in the insulator layers. This construction made of a plurality of metal areas ensures the mechanical load-carrying capability of the contact terminal that is necessary in the case of a contact connection by probes of a probe card during testing of the integrated semiconductor circuit and in the case of contact connection by bonding wires.

The capacitance of the contact terminal with respect to the substrate is determined by the distance between the contact terminal and the substrate. The smaller the distance between the bottommost metal area of the stack that forms the contact terminal, the larger the capacitance. It may be desirable, therefore, for the bottommost metal area of the contact terminal to be at a maximum distance from the substrate. To put it another way, for a given number of wiring planes, beginning from the topmost wiring plane, as few wiring planes as possible should be used for the formation of the contact terminal.

It is evident that simultaneous optimization with regard to the mechanical stability and the electrostatic capacitance of the contact terminal with respect to the substrate is not possible. In the case of the mechanical stability requirements of the contact terminal, the latter thus has a minimum capacitance with respect to the substrate which cannot be reduced.

### SUMMARY OF THE INVENTION

An object of the present invention is to provide an integrated semiconductor circuit and a method for producing the same which enable a lower electrostatic capacitance between the contact terminal and the substrate.

Embodiments of the present invention are based on the insight that omission of bonding during the flip-chip mounting—use of which is becoming increasingly widespread—of chips on other chips, on printed circuit boards, or circuit boards means that the contact terminals are mechanically loaded only during testing by the probes of the probe card. Embodiments of the present invention are furthermore based on the idea of providing different contact terminals for the testing of an integrated semiconductor circuit, that is to say for the temporary contact connection of the contact terminals by probes of a probe card, and for the permanent contact connection in the case of flip-chip mounting. A contact terminal for the testing of the integrated semiconductor circuit comprises, in a manner similar to a conventional contact terminal, a stack of metal areas that are formed in a plurality of wiring planes lying one above the other. A contact terminal for a permanent contact connection after testing by means of flip-chip mounting comprises a single metal area, which may be arranged in the topmost wiring plane, or a stack of metal areas whose bottommost metal area is at a greater distance from the substrate than the bottommost metal area of the contact terminal provided for testing.

One advantage of the present invention consists in the fact that, independently of one another, the contact terminal provided for testing can be optimized with regard to its mechanical stability and the contact terminal provided for the subsequent permanent contact connection can be optimized with regard to a minimum capacitance with respect to the substrate. In particular, the contact terminal provided for the permanent contact connection in the case of flip-chip mounting has, relative to its area, a lower electrostatic capacitance with respect to the substrate than the contact provided for the testing of the semiconductor circuit.

Furthermore, the two contact terminals can also be optimized independently of one another with regard to their lateral extent or their area, so that both the contact terminal provided for the temporary contact connection by a probe of a probe card and the contact terminal provided for a permanent contact connection in the case of flip-chip mounting have the required minimum area in each case.

If the area required for the contact connection by a probe of a probe card is significantly smaller than the area required for the permanent contact connection in the case of flip-chip mounting, it is already possible, simply by connecting the two contact terminals in parallel, to reduce their total capacitance with respect to the substrate in comparison with the conventional contact pad. Otherwise, a switch may be arranged between the contact terminal provided for testing and the signal path assigned to it. The switch, depending on its arrangement, is opened after testing in order to isolate the contact terminal provided for testing from the signal path, or is closed in order, by way of example, to short-circuit an amplifier that is only assigned to the contact terminal provided for testing. Instead of a switch, however, other circuits or a corresponding design of amplifiers or drivers between the signal path and the contact terminal provided for testing may also be used to prevent, suppress, or reduce the capacitance between the contact terminal provided for testing and the other contact terminal and the signal path.

The present invention thus for the first time simultaneously enables a mechanical stability sufficient for testing by means of a probe card and a low capacitance and correspondingly high data transfer rate during normal operation.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic illustration of a vertical section through an integrated semiconductor circuit according to one embodiment of the present invention;

FIG. 2 shows a schematic circuit diagram of an integrated semiconductor circuit according to one embodiment of the present invention;

FIG. 3 shows a schematic circuit diagram of an integrated semiconductor circuit according to one embodiment of the present invention; and

FIG. 4 shows a schematic flow diagram of a production method according to one embodiment of the present invention.

### DETAILED DESCRIPTION OF THE PREFERRED EMBODIMENT

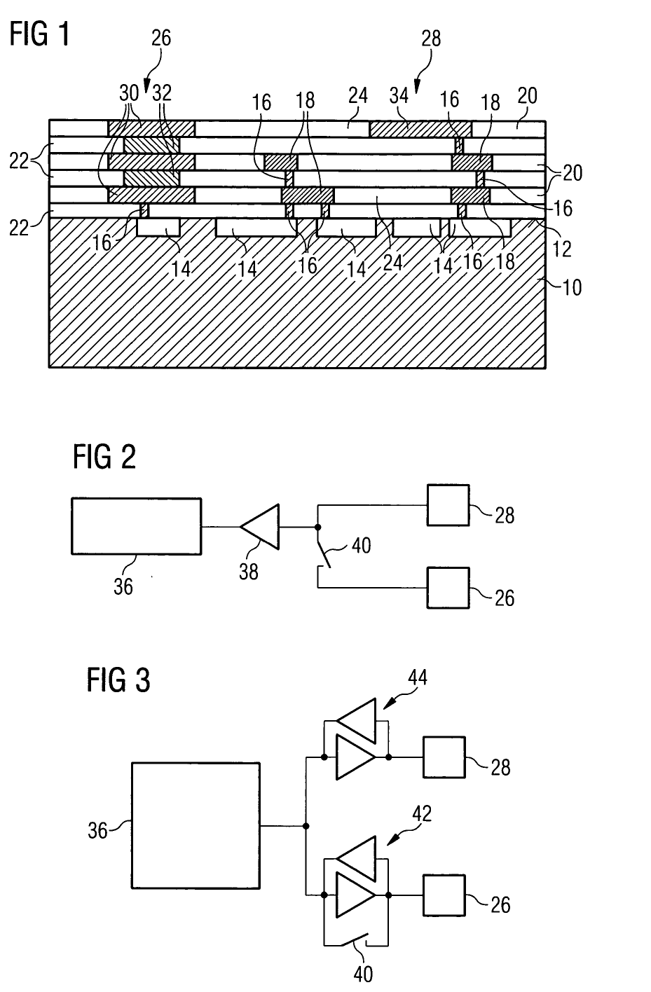

FIG. 1 is a schematic illustration of a vertical section through an integrated semiconductor circuit in accordance with one embodiment of the present invention. In a substrate 10, electronic components 14 are arranged at the surface 12 thereof. The components 14 may be transistors, diodes, capacitors, resistors or other components. If the integrated semiconductor circuit is a memory circuit, for example a DRAM memory circuit, the components 14 may be memory cells, input and output amplifiers or drivers, row and column decoders, and other circuits or subcircuits of the memory circuit. For this purpose, the components 14 are interconnected or connected to one another via through-hole conductors 16 and interconnects 18.

The interconnects 18 are arranged in a plurality of wiring planes 20 that are isolated from one another and from the substrate 10 or the surface 12 thereof in each case by an insulator layer 22. Interconnects 18 and other conductive structures—described below—made of a metal are formed within each wiring plane 20 and are laterally isolated and insulated from one another by an electrically insulating material 24. The through-hole conductors 16 are arranged in the insulator layers 22 and in each case connect one interconnect 18 to another interconnect 18 or to a component 14.

A first contact terminal 26 and a second contact terminal 28 are formed in the wiring planes 20. The first contact terminal 26 comprises a stack of metal areas 30 in a plurality (in this example in all) of the wiring planes 20. These metal areas 30 have in each case approximately the same extent in the lateral direction and are connected to one another in the vertical direction by means of through-hole conductors, conductive ridges 32 or other electrically conductive structures. Because of the structure described, the first contact terminal 26 has a high mechanical stability and can therefore readily be contact-connected by a probe of a probe card or else by bonding by means of a bonding wire.

The second contact terminal 28 comprises a metal area 34 arranged in the topmost wiring plane 20. The second contact terminal 28 is thus at a substantially greater distance from the surface 12 of the substrate 10 than the first contact terminal 26. The capacitance of the second contact terminal 28 with respect to the substrate is therefore a corresponding factor lower than the capacitance of the first contact terminal 26 with respect to the substrate 10. The consequence of this is that data and other signals can be transferred at a higher speed or rate via the second contact terminal 28 than via the first contact terminal 26.

As an alternative, the second contact terminal 28 could also comprise a stack of metal areas 34, the bottommost metal area 34 of the second contact terminal 28 being at a greater distance from the surface 12 of the substrate 10 than the bottommost metal area 30 of the first contact terminal 26.

Both the first contact terminal 26 and the second contact terminal 28 are connected via through-hole conductors 16 and interconnects 18 to further structures, for example to internal data, address or control lines of the integrated semiconductor circuit or else to amplifier or driver circuits which are formed from components 14 and which, in turn, may be connected to data, address or control lines.

FIG. 2 is a schematic circuit diagram illustrating a detail from an integrated semiconductor circuit in accordance with one embodiment of the present invention. A signal path 36 may provide a data, address or control line or some other structure of the circuit via which a signal is transferred and which the integrated semiconductor circuit receives from an external signal source or transmits to an external signal receiver. The signal path 36 is connected via an amplifier 38 to a first contact terminal 26 and a second contact terminal 28 in order to receive via these signals from an external signal source. The first contact terminal 26 is provided for a contact connection by a probe of a probe card during a test of the integrated semiconductor circuit and is constructed in the manner illustrated above with reference to FIG. 1 in order to have the corresponding mechanical stability.

A switch 40 is arranged between the first contact terminal 26 and the amplifier 38, with the switch being closed during the testing of the integrated semiconductor circuit, so that a signal present at the first contact terminal 26 is conducted to the amplifier 38. After the testing of the integrated semiconductor circuit, the probe of the probe card is removed from the first contact terminal 26 and the switch 40 is opened. For this purpose, the switch 40 is preferably designed as a fuse or fusible component. By momentarily feeding in a high current or by radiating in focused laser light, a conductive structure of the fuse is vaporized in order to break the direct electrical connection between the first contact terminal 26 and the amplifier 38. Instead of a fuse, it is also possible to use any other arbitrary switch which can preferably change its switching state permanently by means of a single switching signal.

The second contact terminal 28 is constructed in the manner described above with reference to FIG. 1. It therefore has only a low mechanical stability, which, however, suffices for an electrical contact connection in the case of flip-chip mounting, and a low electrostatic capacitance with respect to the substrate 10. The second contact terminal 28 is continuously connected to the input of the amplifier 38. As an alternative, it is connected to the input of the amplifier 38 via a switch during normal operation of the integrated semiconductor circuit.

As a result of the switch 40 being opened after the test in the integrated semiconductor circuit, the first contact terminal 26 no longer has an influence on the capacitance of the input of the integrated semiconductor circuit that is formed by the second contact terminal 28 and the amplifier 38. Said input thus has a low capacitance, so that data, addresses, control and other signals can be transferred at a high speed.

On account of the arrangement of the amplifier 38, the input illustrated in FIG. 2 is suitable for receiving signals from an external signal source, but not for transmitting signals to an external signal receiver. The input illustrated in FIG. 2 is therefore, for example, an address or control signal input of a memory circuit via which the latter only receives, but does not transmit, address or control signals. If the input and output of the amplifier 38 are interchanged, the subcircuit illustrated in FIG. 2 is suitable as a pure output via which signals are only transmitted, but not received. As an alternative, an amplifier 38 or an arrangement of a plurality of amplifiers 38 is provided, such that it is possible both to receive signals from an external signal source and to transmit signals to an external signal receiver.

FIG. 3 is a schematic circuit diagram illustrating a detail from an integrated semiconductor circuit in accordance with a further exemplary embodiment of the present invention. This exemplary embodiment differs from that illustrated above with reference to FIG. 2 in that each of the contact terminals 26, 28 is assigned a dedicated amplifier or a dedicated amplifier circuit 42, 44. The amplifier circuits 42, 44 are illustrated in FIG. 3 such that they comprise two individual amplifiers in each case and amplify signals in both directions. The subcircuit illustrated is thus suitable both as an input and as an output. As an alternative, each of the amplifier circuits 42, 44 is constructed such that it is suitable only for amplification in one direction, in a manner similar to the illustration in FIG. 2.

The exemplary embodiment illustrated in FIG. 3 furthermore differs from that illustrated above with reference to FIG. 2 in that the switch 40 does not effect a direct electrical isolation between the first contact terminal 26 and the signal path 36, but rather a short circuit of the first amplifier circuit 42 or of the input and output thereof. The short-circuiting of the first amplifier circuit 42 reduces or minimizes the influence of the electrostatic capacitance of the first contact terminal 26 on signals that run via the signal path 36, the first amplifier circuit 42 and the second contact terminal 28. A signal transfer at a high speed via the second contact terminal 28 is then no longer impaired, or no longer significantly impaired, by the capacitance of the first contact terminal 26 with respect to the substrate.

While the switch 40 in the exemplary embodiment illustrated above with reference to FIG. 2 is closed during the testing of the integrated semiconductor circuit and is subsequently opened, the switch 40 in the case of the exemplary embodiment illustrated with reference to FIG. 3 is opened during the testing of the integrated semiconductor circuit and is subsequently closed during normal operation thereof.

As an alternative to the arrangement of the switch 40 as illustrated with reference to FIG. 3, said switch is arranged upstream or downstream of the first amplifier circuit 42, that is to say between the first contact terminal 26 and the first amplifier circuit 42 or between the first amplifier circuit 42 and the signal path 36. In this arrangement, the switch 40, as in the case of the exemplary embodiment illustrated above with reference to FIG. 2, is closed during the testing of the integrated semiconductor circuit and is subsequently opened during normal operation thereof.

One advantage of the exemplary embodiment illustrated with reference to FIG. 3 is that the properties of each of the amplifier circuits 42, 44 can be specially configured for the contact terminal 26, 28 connected to it, in particular to compensate for the electrostatic capacitance thereof. One advantage of the exemplary embodiment illustrated above with reference to FIG. 2 is that only one amplifier 38 or one amplifier circuit is necessary, whereby chip area and hence production costs are saved.

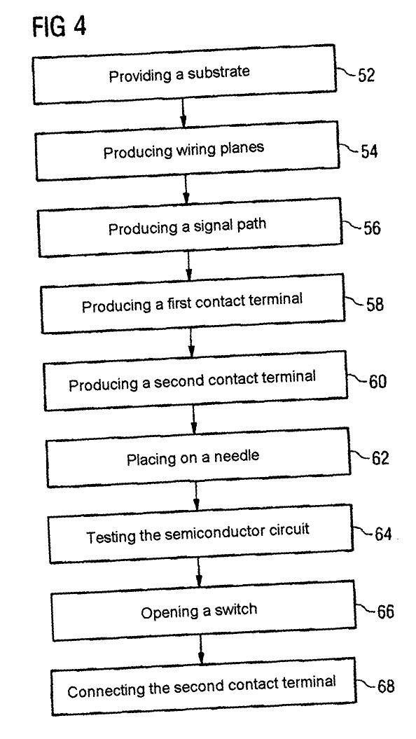

FIG. 4 is a schematic flow diagram of a production method in accordance with an exemplary embodiment of the present invention.

A first step 52 involves providing a substrate 10 with a circuit, as has been illustrated above with reference to FIG. 1, for example. A second step 54 involves producing a plurality of wiring planes 20 with intervening insulator layers 22 on the surface 12 of the substrate 10, so that the wiring planes 20 are isolated and electrically insulated from one another and from the surface 12 of the substrate 10 by the insulator layers 22. Each wiring plane 20 contains one or more conductor structures 18 which are connected to one another and to components 14 in the substrate 10 by means of through-hole conductors 16 in the insulator layers 22. A third step 56, which is preferably performed at the same time as the production of the interconnects and/or components 14 in the substrate 10, involves producing a signal path 36 comprising interconnects 18 in wiring planes 20 and/or components 14 in the substrate 10.

A fourth step 58 involves producing a first contact terminal 26 made of a stack of metal areas 30 in a plurality of the wiring planes 20. A fifth step 60 involves producing a second contact terminal 28 made of a metal area 34 or a stack of metal areas, the bottommost metal area of the second contact terminal 28 being at a greater distance from the surface 12 of the substrate 10 than the bottommost metal area of the first contact terminal 26. The fourth step 58 and the fifth step 60 are preferably likewise effected at the same time as the production of the wiring plane 20 and the insulator layers 22.

A sixth step 62 involves placing a probe of a probe card onto the first contact terminal 26 in order to produce an electrical connection between the same. The integrated semiconductor circuit is tested via this electrical connection in a seventh step 64.

After the testing of the semiconductor circuit, the switching state of the switch 40 is preferably changed in order to isolate the first contact terminal 26 from the signal path 36 or at least to reduce the influence of the electrostatic capacitance between the first contact terminal 26 and the substrate 10 on signals that are transferred via the second contact terminal 28.

In a ninth step 68, the second contact terminal 28 is connected to a further integrated semiconductor circuit or a circuit board. This is preferably effected by means of flip-chip mounting.

While the foregoing is directed to embodiments of the present invention, other and further embodiments of the invention may be devised without departing from the basic scope thereof, and the scope thereof is determined by the claims that follow.

What is claimed is:

1. An integrated semiconductor circuit comprising:
a substrate with a circuit;
a plurality of wiring planes that are isolated from one another and from the substrate by insulator layers;
a signal path for the circuit in the substrate and the plurality of wiring planes;
a first contact terminal, comprising a stack of metal areas in the plurality of the wiring planes and configured to connect the signal path to a first external device during a test of the integrated semiconductor circuit; and
a second contact terminal comprising a metal area in one of the plurality of wiring planes for connecting the signal path to second external device during normal operation of the integrated semiconductor circuit, wherein a first distance between the substrate and a bottommost portion of the second contact terminal is greater than a second distance between the substrate and a bottommost metal area of the stack of the first contact terminal.

2. The integrated semiconductor circuit of claim 1, wherein the second contact terminal further comprises a second stack of metal areas in the plurality of wiring planes, and wherein a distance between the bottommost metal area of the second stack of the second contact terminal and the substrate is greater than the second distance between the bottommost metal area of the stack of the first contact terminal and the substrate.

3. The integrated semiconductor circuit of claim 1, in which the first contact terminal is used to create a temporary contact connection for a probe card and the second contact terminal is used to create a permanent contact connection by flip-chip mounting on a further substrate.

4. The integrated semiconductor circuit of claim 1, in which the second contact terminal, relative to the substrate, has a lower capacitance than the first contact terminal.

5. The integrated semiconductor circuit of claim 1, in which the signal path is a data line or an address line or a control line.

6. An integrated semiconductor circuit comprising:
means for supporting comprising a circuit;
a plurality of wiring planes that are isolated from one another and from the means for supporting by means for insulating;
means for conducting a signal for the circuit in the means for supporting and the wiring planes;
a first means for contacting, comprising a first stack of metal areas in the plurality of the wiring planes and configured to connect the means for conducting the signal to a first external device during a test of the integrated semiconductor circuit; and
a second means for contacting comprising a metal area in a wiring plane for connecting the signal path to second external device during normal operation of the integrated semiconductor circuit, wherein a first distance between a bottommost portion of the second means for contacting and the means for supporting is greater than a second distance between a bottommost metal area of the first stack of the first means for contacting and the means for supporting.

7. The integrated semiconductor circuit of claim 6, wherein the second means for contacting further comprises a second stack of metal areas in the plurality of wiring planes, and wherein a distance between a bottommost metal area of the second stack of the second contact terminal and the substrate is greater than the second distance between the bottommost metal area of the first stack of the first contact terminal and the substrate.

8. The integrated semiconductor circuit of claim 6, in which the first means for contacting is used to create a temporary connection for a probe card and the second contact terminal is used to create a permanent contact connection by flip-chip mounting on a further means for supporting.

9. The integrated semiconductor circuit of claim 6, in which the second means for contacting, relative to the means for supporting, has a lower capacitance than the first contact terminal.

10. An integrated semiconductor circuit comprising:
a substrate with a circuit;
a plurality of wiring planes that are isolated from one another and from the substrate by insulator layers;
a signal path for the circuit in the substrate and the plurality of wiring planes;
a first contact terminal, comprising a first stack of metal areas in the plurality of the wiring planes and configured to connect the signal path to a first external device during a test of the integrated semiconductor circuit;
a second contact terminal comprising a metal area in one of the plurality of wiring planes for connecting the signal path to second external device during normal operation of the integrated semiconductor circuit, wherein a first distance between a bottommost portion of the second contact terminal and the substrate is greater than a second distance between a bottommost metal area of the first stack of the first contact terminal and the substrate, wherein the second contact terminal, relative to the substrate, has a lower capacitance than the first contact terminal, relative to the substrate; and
a switch between the first contact terminal and the signal path.

11. The integrated semiconductor circuit of claim 10, wherein the switch is closed during the test of the integrated semiconductor circuit.

12. The integrated semiconductor circuit of claim 10, wherein the switch is in a first position during the test of the integrated semiconductor circuit and in a second position during operation after testing.

13. The integrated semiconductor circuit of claim 10, wherein the switch is a fuse, and wherein the switch is permanently opened after the test by blowing the fuse.

14. The integrated semiconductor circuit of claim 10, comprising:
an amplifier connected between the signal path and the contact pads.

15. The integrated semiconductor circuit of claim 10, comprising:
a first amplifier connected between the signal path and the first contact terminal; and
a second amplifier connected between the signal path and the second contact terminal.

16. The integrated semiconductor circuit of claim 15, wherein the switch connected in parallel across an input and an output of the first amplifier in order to short-circuit the amplifier after the test.

17. A method for producing an integrated semiconductor circuit, wherein the semiconductor circuit comprises a substrate with a circuit, the method comprising:
creating a plurality of wiring planes on the substrate, the wiring planes being isolated from one another and from the substrate by insulator layers;
creating a signal path in the wiring planes and the substrate;
creating a first contact terminal from a first stack of metal areas in the plurality of the wiring planes, configured to connect the signal path to one of a first external signal source and a first external signal receiver;
creating a second contact terminal from one of a metal area in a wiring plane and a second stack of metal areas in the plurality of wiring planes, configured to connect the signal path to one of a second external signal source and a second external signal receiver, wherein a first distance between the metal area or a bottommost metal area of the second stack of the second contact terminal and the substrate is greater than a second distance between a bottommost metal area of the first stack of the first contact terminal and the substrate.

18. The method of claim 17, furthermore comprising the following steps of:
temporarily connecting a probe of a probe card to the first contact terminal in order to produce an electrical connection between the probe and the first contact terminal;
testing the integrated semiconductor circuit using the electrical connection between the probe and the first contact terminal; and
connecting the second contact terminal to a further integrated semiconductor circuit or a circuit board.

19. The method of claim 17, further comprising:
during testing, connecting the first contact terminal to the signal path by closing a switch.

20. The method of claim 17, further comprising:
after testing, disconnecting the first contact terminal from the signal path by opening a switch.

21. The method of claim 20, wherein the switch is permanently opened by blowing a fuse.

22. A semiconductor device comprising:
a substrate;
a first contact comprising a plurality of overlapping metal areas, wherein each metal area is approximately the same area, and wherein each overlapping metal area is in a different layer of the semiconductor device, including a topmost layer of the semiconductor device; and
a second contact area comprising a metal area arranged in the topmost layer of the semiconductor device, wherein the second contact area has a lower capacitance with respect to the substrate than the first contract, and wherein the first contact and the second contact are used to access a signal path of the semiconductor device.

23. The semiconductor device of claim 22, wherein the plurality of metal areas are connected in the vertical direction by one of through-hole conductors and conductive ridges.

24. The semiconductor device of claim 22, wherein one of a probe of a probe card and a bonding wire are placed in contact with the first contact.

25. The semiconductor device of claim 22, wherein a first distance from a lowermost point of the first contact to the substrate is smaller than a second distance from a lowermost point of the second contact to the substrate.

26. The semiconductor device of claim 25, wherein the second contact comprises a second plurality of overlapping areas.

27. The semiconductor device of claim 22, wherein the second contact is a single layer of metal.

28. A method of testing an integrated semiconductor circuit, wherein the semiconductor circuit comprises a substrate with a circuit, the method comprising:
connecting a probe of a probe card to a first contact of the semiconductor device, wherein the first contact comprises a first stack of metal areas in a plurality of a wiring planes of the integrated semiconductor circuit and wherein the first contact is connected to a signal path of the integrated semiconductor circuit;
testing the integrated semiconductor circuit using the probe card;
after testing, connecting the semiconductor circuit to a further integrated semiconductor circuit or a circuit board, wherein the connection after testing is made using a second contact terminal connected to the signal path, wherein the second contact terminal comprises one of a metal area in an uppermost wiring plane and a second stack of metal areas in the plurality of wiring planes, wherein the second contact terminal is connected to the signal path, wherein a first distance between the metal area or a bottommost metal area of the second stack of the second contact terminal and the substrate is greater than a second distance between a bottommost metal area of the first stack of the first contact terminal and the substrate.

29. The method of claim 28, further comprising:
during testing, connecting the first contact terminal to the signal path by closing a switch.

30. The method of claim 28, further comprising:
after testing, disconnecting the first contact terminal from the signal path by opening a switch.
